(19) United States
(12) Patent Application Publication
(10) Pub. No.: US 2023/0249286 A1
(43) Pub. Date: Aug. 10, 2023

(54) APPARATUS FOR MANUFACTURING DISPLAY DEVICE AND METHOD OF MANUFACTURING DISPLAY DEVICE

(71) Applicant: SAMSUNG DISPLAY CO., LTD., Yongin-si (KR)

(72) Inventors: Heungyeol NA, Yongin-si (KR); Jungwoo CHOI, Yongin-si (KR); Yonghyun KIM, Yongin-si (KR)

(21) Appl. No.: 18/163,327

(22) Filed: Feb. 2, 2023

(30) Foreign Application Priority Data
Feb. 9, 2022 (KR) 10-2022-0016966

(51) Int. Cl. B23K 26/08; H10K 59/12; B23K 26/12

(52) U.S. Cl. CPC B23K 26/0838; H10K 59/1201; B23K 26/127

(57) ABSTRACT

An apparatus for manufacturing a display device include: a tray on which a window is seated, a belt on which the tray is seated, where the tray is moved by the belt, a first pulley which rotatably supports the belt, a second pulley arranged to be spaced apart from the first pulley, where the second pulley rotatably supports the belt, and a driving portion connected to the second pulley, where the driving portion rotates the second pulley.

This application claims priority to Korean Patent Application No. 10-2022-0016966, filed on Feb. 9, 2022, and all the benefits accruing therefrom under 35 U.S.C. § 119, the content of which in its entirety is herein incorporated by reference.

### BACKGROUND

### 1. Field

One or more embodiments relate to an apparatus and a method of manufacturing a device, and more particularly, to an apparatus for manufacturing a display device and a method of manufacturing a display device using the apparatus.

### 2. Description of the Related Art

Electronic devices based on mobility are widely used. Recently, tablet personal computers (PCs) have been widely used as mobile electronic devices in addition to small electronic devices such as mobile phones.

Such a movable (or portable) electronic device includes a display device to provide a user with visual information such as an image or video so as to support various functions. Recently, as other components for driving the display device are miniaturized, the importance of the display device in the electronic device is gradually increasing, and an electronic device having a structure allowed to be bent to have a certain angle in a flat state has also been developed.

### SUMMARY

Laser may be used for precise processing during the manufacture of a display device. At this time, a window may be used to prevent dropping of foreign substances generated during the use of laser. Various devices may be used to provide such a window in a correct location. At this time, when such a system does not work precisely, the display device may be broken during manufacture.

One or more embodiments include an apparatus for manufacturing a display device that may be precisely processed and a method of manufacturing a display device.

According to one or more embodiments, an apparatus for manufacturing a display device includes a tray on which a window is seated, a belt on which the tray is seated, where the tray is moved by the belt, a first pulley which rotatably supports the belt, a second pulley disposed to be spaced apart from the first pulley, where the second pulley rotatably supports the belt, and a driving portion connected to the second pulley, where the driving portion rotates the second pulley.

In an embodiment, the apparatus may further include a sensor portion which detects the position of one point of the belt.

In an embodiment, the apparatus may further include a controller which determines whether the belt is abnormal based on the position of the one point detected by the sensor portion.

In an embodiment, the apparatus may further include a position adjusting portion which adjusts a distance between the first pulley and the second pulley based on the result of determining whether the belt is abnormal.

In an embodiment, the apparatus may further include a chamber in which the belt, the first pulley and the second pulley are disposed.

In an embodiment, the apparatus may further include a tray providing portion connected to the chamber, where the tray providing portion provides a new tray, on which a new window is disposed, to the belt.

In an embodiment, the apparatus may further include a laser irradiating portion disposed outside the first chamber, where the laser irradiating portion radiates laser into the chamber.

In an embodiment, the apparatus may further include a transmission window, which is disposed in the chamber and through which the laser transmits.

In an embodiment, the apparatus may further include a substrate fixing portion disposed on the tray, where the substrate fixing portion fixes the substrate thereto.

According to one or more embodiments, a method of manufacturing a display device includes arranging a substrate in a chamber, moving a first tray, in which a first window is disposed, to a position in the change corresponding to the substrate, detecting a position of one point of a belt when the first tray is moved, and determining whether the belt is abnormal based on the position of the one point of the belt.

In an embodiment, the method may further include maintaining a pressure inside the chamber to be lower than an atmospheric pressure.

In an embodiment, the method may further include replacing the first tray with a second tray, in which a second window is disposed, by using a tray providing portion connected to the chamber.

In an embodiment, the method may further include transporting the second tray to the chamber by using the tray providing portion connected to the chamber.

In an embodiment, the method may further include maintaining a pressure inside the tray providing portion to be the same as the pressure inside the chamber.

In an embodiment, the method may further include radiating laser onto the substrate by passing the first window.

In an embodiment, the method may further include comparing an actual movement distance of the first tray, at which the first tray is actually moved, with a signal movement distance, at which the first tray is pre-set to be moved in response to an external signal.

In an embodiment, the method may further include adjusting a tensile force of the belt by comparing the actual movement distance with the signal movement distance.

In an embodiment, the method may further include adjusting the position of a pulley, which rotatably supports opposing ends of the belt to rotate the belt.

In an embodiment, the method may further include fixing the substrate in a predetermined position in the chamber.

In an embodiment, the laser may be radiated into the first chamber from an outside of the chamber.

These general and concrete features of embodiments may be implemented using systems, methods, computer programs, or any system, method, and combination of computer programs.

### BRIEF DESCRIPTION OF THE DRAWINGS

The above and other features of certain embodiments of the disclosure will be more apparent from the following description taken in conjunction with the accompanying drawings, in which:

FIG. 1 is a cross-sectional view schematically illustrating an apparatus for manufacturing a display device according to an embodiment;

FIG. 2 is a perspective view schematically illustrating a part of the apparatus for manufacturing the display device shown in FIG. 1;

FIG. 3 is a front view schematically illustrating the position of a tray of the apparatus for manufacturing the display device shown in FIG. 1;

FIG. 4 is a block diagram schematically illustrating a control flow of the apparatus for manufacturing the display device shown in FIG. 1;

FIG. 5 is a plan view schematically illustrating a display device according to an embodiment; and

FIG. 6 is a cross-sectional view of the display device taken along line VI-VI′ of FIG. 5.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art.

Like reference numerals refer to like elements throughout. “Or” means “and/or.” As used herein, the term “and/or” includes any and all combinations of one or more of the associated listed items. Throughout the disclosure, the expression “at least one of a, b or c” or “at least one selected from a, b and c” indicates only a, only b, only c, both a and b, both a and c, both b and c, all of a, b, and c, or variations thereof.

Since various modifications and various embodiments of the present disclosure are possible, specific embodiments are illustrated in the drawings and described in detail in the detailed description. Effects and features of the present disclosure, and a method of achieving them will be apparent with reference to embodiments described below in detail in conjunction with the drawings. However, the present disclosure is not limited to the embodiments disclosed herein, but may be implemented in a variety of forms.

It will be understood that when an element is referred to as being “on” another element, it can be directly on the other element or intervening elements may be present therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an”.

It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

In the drawings, for convenience of description, the sizes of components may be exaggerated or reduced. For example, since the size and thickness of each component shown in the drawings are arbitrarily indicated for convenience of description, the present disclosure is not necessarily limited to the illustration.

In the following embodiments, the X-axis, Y-axis, and Z-axis are not limited to three axes on an orthogonal coordinate system, and may be interpreted in a broad sense including this case. For example, the X-axis, the Y-axis, and the Z-axis may be orthogonal to each other, but may refer to different directions that do not orthogonal to each other.

In the case where some embodiments may be implemented in the present specification, a specific process order may be performed differently from the order described. For example, two processes described in succession may be substantially performed at the same time, or in an opposite order to an order to be described.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims

Hereinafter, embodiments of the disclosure will be described in detail with reference to the accompanying drawings. The same or corresponding components are denoted by the same reference numerals, and any repetitive detailed description of the same or like components may be omitted or simplified.

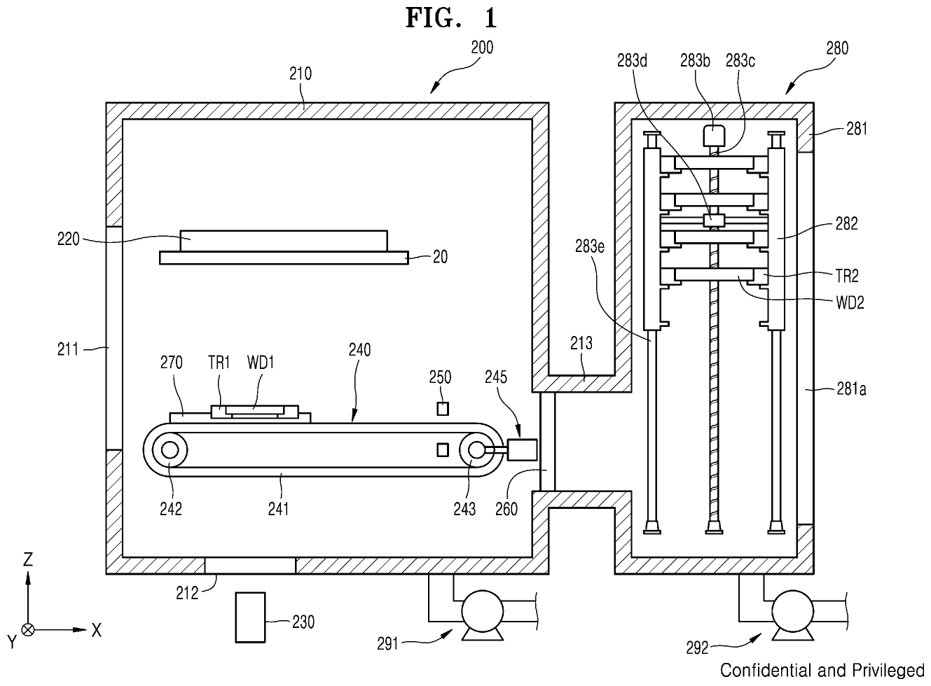

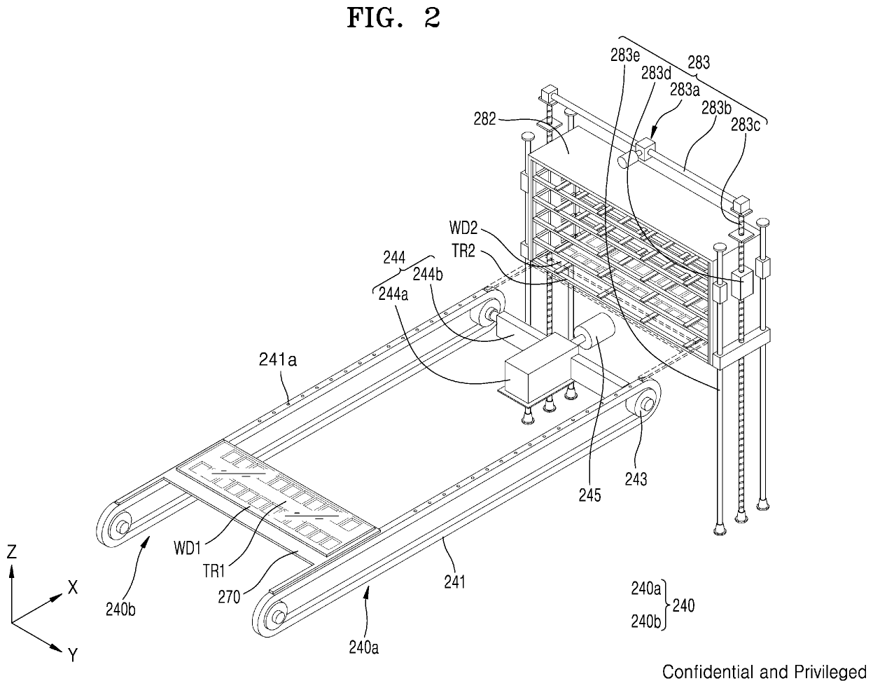

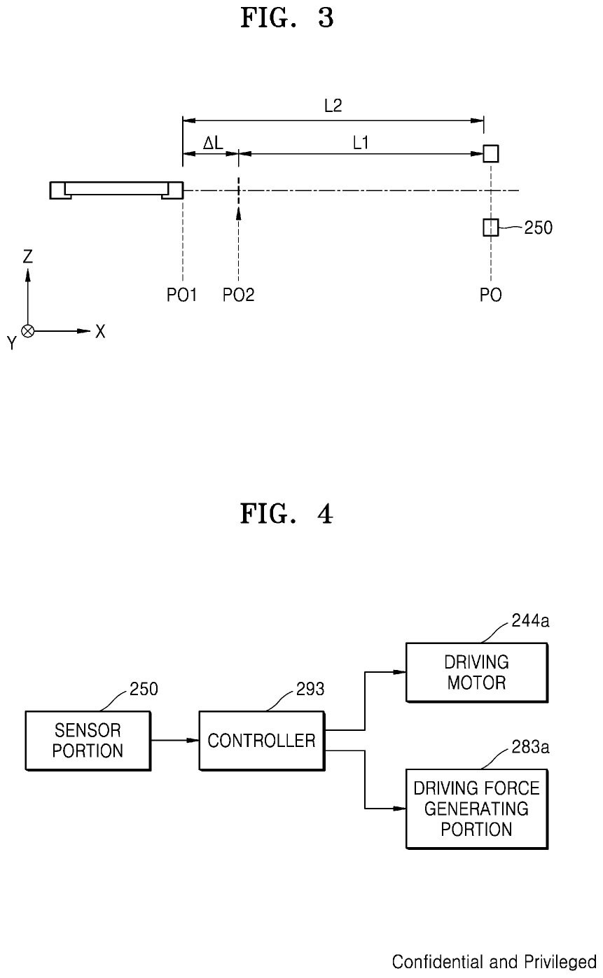

FIG. 1 is a cross-sectional view schematically illustrating an apparatus for manufacturing a display device according to an embodiment. FIG. 2 is a perspective view schematically illustrating a part of the apparatus for manufacturing the display device shown in FIG. 1. FIG. 3 is a front view schematically illustrating the position of a tray of the apparatus for manufacturing the display device shown in FIG. 1. FIG. 4 is a block diagram schematically illustrating a control flow of the apparatus for manufacturing the display device shown in FIG. 1.

Referring to FIGS. 1 through 4, an embodiment of an apparatus 200 for manufacturing a display device may include a process portion and a tray providing portion 280. The process portion and the tray providing portion 280 may be connected to each other. In an embodiment, the process portion and the tray providing portion 280 may be constantly or selectively connected to each other. Herein, for convenience of description, embodiments where the process portion and the tray providing portion 280 are selectively connected to each other, are described in detail.

In an embodiment, the process portion may include a first chamber 210, a substrate fixing portion 220, a laser irradiating portion 230, a tray transporting portion 240, a sensor portion 250, an opening/closing portion 260, a transfer 270, and a first pressure adjusting portion 291.

A part of the first chamber 210 may be formed to be opened, and may be connected to the tray providing portion 280. In an embodiment, the tray providing portion 280 and the first chamber 210 may be connected to each other via a connection chamber 213.

A first chamber opening/closing portion 211 may be arranged (or disposed) in the opened part of the first chamber 210. In an embodiment, the first chamber opening/closing portion 211 may be formed in the form of a gate valve and may selectively open or close the opened part of the first chamber 210.

The first chamber 210 described above may include a transmission window 212. In an embodiment, the transmission window 212 may be arranged to correspond to the position of the laser irradiating portion 230, and may include a transparent material. In such an embodiment, the transmission window 212 may be arranged to correspond to a position in which a process is performed.

The substrate fixing portion 220 may be disposed above the first tray TR1. The substrate fixing portion 220 may fix a display substrate 20 thereto. In an embodiment, the display substrate 20 may include a substrate and at least one layer arranged on the substrate. In an embodiment, for example, the display substrate 20 may include a substrate, a thin film transistor arranged on the substrate, and an organic light emitting diode arranged on the thin film transistor. In such an embodiment, the display substrate is not limited to those described above and may be in a state in which various layers are formed on the substrate.

The substrate fixing portion 220 described above may include an adhesive chuck or an electrostatic chuck for fixing the display substrate 20 thereto. In an embodiment, the substrate fixing portion 220 may be formed to be fixed in a predetermined portion or movable in the first chamber 210. In an embodiment, for example, when the substrate fixing portion 220 is fixed in the first chamber 210, the display substrate 20 may be inserted into the first chamber 210 via a robot arm arranged outside the first chamber 210 and may be fixed to the substrate fixing portion 220. In an alternative embodiment, when the substrate fixing portion 220 is linearly movable, the substrate fixing portion 220 may be formed in the form of a shuttle, and after the substrate fixing portion 220 is drawn out of the first chamber 210, the substrate fixing portion 220 may fix the display substrate 20 thereto and thus may be moved from the outside to the inside of the first chamber 210.

The laser irradiating portion 230 may be arranged outside the first chamber 210 and may radiate laser beams into the first chamber 210. In an embodiment, the laser beams radiated by the laser irradiating portion 230 may pass through the transmission window 212 to pass through a window (e.g., a first window WD1 in FIG. 1) and then may be radiated onto the display substrate 20. The laser beams may be radiated in partial regions of the display substrate 20, thereby removing or crystallizing at least part of at least one layer of the display substrate 20.

The tray transporting portion 240 may transport a tray. In an embodiment, a pair of tray transporting portions 240 may be provided. In an embodiment, for example, the pair of tray transporting portions 240 may include a first tray transporting portion 240a and a second tray transporting portion 240b, which are arranged to be spaced apart from each other. In such an embodiment, the first tray transporting portion 240a and the second tray transporting portion 240b may transport the tray by supporting the transfer 270. In such an embodiment, the first tray transporting portion 240a and the second tray transporting portion 240b may be the same as or similar to each other. Thus, hereinafter, the first tray transporting portion 240a will be described in detail.

The first tray transporting portion 240a may include a belt 241, a first pulley 242, a second pulley 243, a driving portion 244, and a position adjusting portion 245.

The belt 241 may include or be made of a metal material. In an embodiment, the belt 241 may be formed in the form of a ring and may be wound on the first pulley 242 and the second pulley 243 and may rotate. In an embodiment, the belt 241 may be formed in various forms. In an embodiment, for example, the belt 241 may be in the form of a belt having no unevenness on the surface. In an alternative embodiment, although not shown, the belt 241 may be formed in the form of a timing belt. However, herein, for convenience of description, embodiments where the belt 241 is a steel belt having a flat surface are described in detail.

The belt 241 described above may also be arranged in a separate accommodating portion although not shown. In an embodiment, the accommodating portion may be formed so that an upper side thereof is opened, may expose the upper surface of the belt 241 and may surround side surfaces of the belt 241.

The first pulley 242 and the second pulley 243 may be arranged to be spaced apart from each other, and may rotatably support the belt 241. When the first pulley 242 and the second pulley 243 are rotated, the belt 241 may rotate. In an embodiment, each of the first pulley 242 and the second pulley 243 may have the form of a roller. In an alternative embodiment, protrusions may be on outer surfaces of the first pulley 242 and the second pulley 243, and the first pulley 242 and the second pulley 243 may correspond to concave portions of the belt 241.

The driving portion 244 may be connected to the first pulley 242 and/or the second pulley 243. Herein, for convenience of description, embodiments where the driving portion 244 is connected to the second pulley 243, are described in detail.

The driving portion 244 described above may be provided at each of the first tray transporting portion 240a and the second tray transporting portion 240b or may be connected to the first tray transporting portion 240a and the second tray transporting portion 240b to simultaneously operate the first tray transporting portion 240a and the second tray transporting portion 240b. Herein, for convenience of description, embodiments where a single driving portion 244 is provided and is connected to the first tray transporting portion 240a and the second tray transporting portion 240b, are described in detail.

The driving portion 244 may include a rotation shaft 244b connected to the second pulley 243. The driving portion 244 may rotate the second pulley 243. Also, the driving portion 244 may include a driving motor 244a that is connected to the rotation shaft 244b to rotate the rotation shaft 244b. In such an embodiment, the rotation directions of the rotation shaft of the driving motor 244a and the rotation shaft 244b may be different from each other. In this case, the rotation shaft of the driving motor 244a and the rotation shaft 244b may be connected to each other via a universal joint or bevel gear to deliver the operation of the driving motor 244a to the rotation shaft 244b.

In embodiments, the driving motor 244a may include an encoder, thereby recognizing an angle (or the number of times) at which the rotation shaft of the driving motor 244a rotates from a certain point.

The position adjusting portion 245 may be connected to the driving portion 244 to vary the position of the driving portion 244. In an embodiment, for example, the position adjusting portion 245 may include a cylinder connected to the driving portion 244. In an alternative embodiment, the position adjusting portion 245 may include a ball screw connected to the driving portion 244, and a motor connected to the ball screw. In another alternative embodiment, the position adjusting portion 245 may include a linear motor connected to the driving portion 244 to vary the position of the driving portion 244. In another alternative embodiment, the position adjusting portion 245 may also include a rack gear connected to the driving portion 244, a spur gear for linearly moving the rack gear, and a motor for rotating the spur gear. In embodiments, the position adjusting portion 245 is not limited to those described above, and may include all structures and all devices connected to the driving portion 244 and linearly moving the driving portion 244.

The position adjusting portion 245 described above is not limited to those described above, may be connected to the second pulley 243 and may vary the position of the second pulley 243. In an alternative embodiment, the position adjusting portion 245 may also be connected to the first pulley 242 to vary the position of the first pulley 242. In another alternative embodiment, the position adjusting portion 245 may be connected to the first pulley 242 and the second pulley 243, respectively, to vary the position of each of the first pulley 242 and the second pulley 243.

in an embodiment, the position adjusting portion 245 described above may be connected to each of the first tray transporting portion 240a and the second tray transporting portion 240b, respectively, and may also be simultaneously connected to the first tray transporting portion 240a and the second tray transporting portion 240b.

Herein, for convenience of description, embodiments where the position adjusting portion 245 is connected to the driving portion 244 and is simultaneously connected to the first tray transporting portion 240a and the second tray transporting portion 240b, are described in detail.

The sensor portion 250 may be disposed to be spaced apart from the belt 241 and may detect a movement distance or a position of one point of the belt 241. In an embodiment, for example, the sensor portion 250 may include an ultrasonic sensor, a hall sensor, a laser sensor, an image sensor, etc. In such an embodiment, the sensor portion 250 may detect the shape of an outer surface of the belt 241. In such an embodiment, the sensor portion 250 may apply a signal to the outer surface of the belt 241 and may detect a signal when a signal reflected from the outer surface of the belt 241 returns to the sensor portion 250. In such an embodiment, the sensor portion 250 may detect time at which a signal is applied to the belt 241 and the signal returns to the sensor portion 250, thereby detecting the position of the transfer 270 and detecting a distance at which the transfer 270 is moved. In an alternative embodiment, the sensor portion 250 may also detect a separate shape arranged on the outer surface of the belt 241. In an embodiment, for example, a plurality of marks 241a may be arranged on the outer surface of the belt 241. In such an embodiment e, the mark 241a may have various shapes. In an embodiment, for example, the mark 241a may have a shape of a groove or a hole, or be made of a different material from a material for forming the belt 241. In such an embodiment, the sensor portion 250 may be arranged in a position corresponding to the mark 241a and may detect time at which a signal reflected from the mark 241a returns to the sensor portion 250, the wavelength of the reflected signal, or whether the signal is reflected or not. Alternatively, the sensor portion 250 may capture or detect an image on the outer surface of the belt 241 on which the mark 241a is arranged.

The opening/closing portion 260 may selectively connect or block the first chamber 210 with or from the tray providing portion 280. In an embodiment, the opening/closing portion 260 may be arranged in the connection chamber 213. In such an embodiment, the opening/closing portion 260 may have a shape of a gate valve.

The transfer 270 may be coupled to the belt 241. In an embodiment, the transfer 270 may be linearly moved based on the rotation of the belt 241. The transfer 270 may include a seating groove on which the tray is seated. In an embodiment, the transfer 270 may pass through the connection chamber 213 based on the movement of the belt 241 and may be inserted into the tray providing portion 280.

The first pressure adjusting portion 291 may be connected to the first chamber 210 and may adjust a pressure inside the first chamber 210. In an embodiment, for example, the first pressure adjusting portion 291 may include a first connection pipe connected to the first chamber 210, and a first pump arranged in the first connection pipe. In such an embodiment, when the first pump operates, the pressure inside the first chamber 210 may be maintained in a lower state than an atmospheric pressure. In an embodiment, for example, the pressure inside the first chamber 210 at which the first pump operates, may be maintained in an almost vacuum state.

The tray providing portion 280 may include a second chamber 281, a cassette 282, a cassette driving portion 283, and a second pressure adjusting portion 292.

The second chamber 281 may have a space therein, that is, a space is defined in the second chamber 281, and the second chamber 281 may be connected to the connection chamber 213. In an embodiment, the second chamber 281 may include an opening region, and a window seated on the tray may be replaced through the opening region. In an embodiment, a second chamber opening/closing portion 281a may be arranged in the opening region of the second chamber 281. In such an embodiment, the second chamber opening/closing portion 281a may have a shape of a door or gate valve.

The cassette 282 may be arranged in the second chamber 281 and may ascend or descend. In an embodiment, the cassette 282 may have a shape of a shelf on which a plurality of trays may be seated.

The cassette driving portion 283 may be arranged inside the second chamber 281, may be connected to the cassette 282 and may ascend/descend the cassette 282. In an embodiment, the cassette driving portion 283 may include a driving force generating portion 283a, a first driving force transferring portion 283b, a second driving force transferring portion 283c, an ascending/descending block 283d, and a guide portion 283e.

The driving force generating portion 283a may include a motor. In an embodiment, the driving force generating portion 283a may further include a decelerator connected to the motor.

The first driving force transferring portion 283b may be connected to a rotation shaft of the driving force generating portion 283a and may transfer a driving force. In an embodiment, the first driving force transferring portion 283b may have a shape of a bar and may be connected to the rotation shaft of the driving force generating portion 283a through a universal joint or bevel gear.

The second driving force transferring portion 283c may be connected to the first driving force transferring portion 283b. In an embodiment, the second driving force transferring portion 283c may have a shape of a screw and may be connected to the first driving force transferring portion 283b through a universal joint or bevel gear.

The ascending/descending block 283d may be arranged at the second driving force transferring portion 283c and may ascend/descend in a lengthwise direction (or a Z-axis direction in FIG. 1) of the second driving force transferring portion 283c when the second driving force transferring portion 283c is rotated. In an embodiment, the ascending/descending block 283d may be connected to the cassette 282.

The guide portion 283e may be connected to the cassette 282 and may guide a movement path of the cassette 282 during the ascending/descending movement of the cassette 282. In an embodiment, the guide portion 283e may include a linear motion guide or a rail. In an alternative embodiment, the guide portion 283e may have a shape of a bar and may also be inserted into the cassette 282. In such an embodiment, a sliding bearing may be arranged at the cassette 282.

The second pressure adjusting portion 292 may be connected to the second chamber 281 and may adjust a pressure inside the second chamber 281. In an embodiment, the second pressure adjusting portion 292 may include a second connection pipe connected to the second chamber 281, and a second pump arranged in the second connection pipe. In such an embodiment, the second pressure adjusting portion 292 may maintain the pressure inside the second chamber 281 to be same as or similar to the atmospheric pressure. Alternatively, the second pressure adjusting portion 292 may maintain the pressure inside the second chamber 281 to be same as or similar to the pressure of the first chamber 210. In such an embodiment, the pressure inside the second chamber 281 may be less than the atmospheric pressure.

The controller 293 may calculate the position of one point of the belt 241 or may calculate the position of the tray based on the result detected by the sensor portion 250. For example, the controller 293 may determine whether the belt 241 is abnormal based on the position of the one point detected by the sensor portion 250. In an embodiment, the controller 293 may include a circuit board arranged in the apparatus 200 for manufacturing a display device or a personal computer arranged outside the apparatus 200 for manufacturing a display device, an additional portable terminal, a laptop computer, a mobile phone, and the like.

In an operation of the apparatus 200 for manufacturing a display device described above, the display substrate 20 may be arranged on the substrate fixing portion 220. Subsequently, a first tray TR1 arranged in the tray transporting portion 240 may be disposed to correspond to the display substrate 20. In an embodiment, a first window WD1 may be arranged on the first tray TR1. In such an embodiment, the first tray TR1 may include a plurality of opening regions spaced apart from each other. That is, the first tray TR1 may be formed in the form of a lattice. The first window WD1 may shield the plurality of opening regions. In an embodiment, a plurality of first windows WD1 may be provided and may be spaced apart from each other to correspond to each of the opening regions. In an alternative embodiment, one first window WD1 may be provided and may shield all of the plurality of opening regions. In another alternative embodiment, a plurality of first windows WD1 may be provided, and each of the plurality of first windows WD1 may also shield the plurality of opening regions. However, herein, for convenience of description, embodiments where only one window WD1 or WD2 is provided, are described in detail.

The display substrate 20 may be arranged on the substrate fixing portion 220 so that the position of the display substrate 20 corresponds to the transmission window 212. Also, the tray transporting portion 240 may be arranged so that the first tray TR1 corresponds to the transmission window 212. In an embodiment, in a plan view, at least a portion of the display substrate 20, the transmission window 212 and the first window WD1 may overlap one another vertically or in the Z-axis direction.

When the laser irradiating portion 230 emits laser beams, the laser beams may pass through the transmission window 212 and the first window WD1 and may be radiated onto the display substrate 20. When laser beams are radiated onto the display substrate 20, the laser beams may be used to remove at least a portion of at least one layer of the display substrate 20. In this case, foreign substances may drop, and the dropping foreign substances may be seated on the first window WD1 and may be prevented from being stacked on the transmission window 212. Also, in the above case, the first pressure adjusting portion 291 may maintain the pressure in the first chamber 210 to be lower than the atmospheric pressure. That is, the first pressure adjusting portion 291 may discharge gas inside the first chamber 210 to the outside.

The above-described operation may be performed on a plurality of display substrates 20. When the above operation is performed on the display substrates 20 by a predetermined number of times, the first tray TR1 may be replaced with a second tray TR2. In this case, a second window WD2 may be arranged on the second tray TR2.

As described above, in a method of replacing the first tray TR1 with the second tray TR2, the tray transporting portion 240 may move the first tray TR1 toward the opening/closing portion 260. Thereafter, the opening/closing portion 260 may be opened to connect the first chamber 210 to the second chamber 281. In this case, the second pressure adjusting portion 292 may adjust the pressure in the second chamber 281 so that the pressure in the second chamber 281 is the same as or similar to the pressure in the first chamber 210.

When the first chamber 210 and the second chamber 281 are connected to each other as described above, the transfer 270 may move to the second chamber 281 through the connection chamber 213 according to rotation of the belt 241 so that the first tray TR1 may be transported to the cassette 282. Thereafter, when the belt 241 rotates as opposed to the above, the transfer 270 may be drawn out of the second chamber 281.

The cassette driving portion 283 may operate so that the second tray TR2 may be disposed in a position corresponding to the transfer 270. Subsequently, the belt 241 rotates again so that the transfer 270 may be inserted into the second chamber 281, and the second tray TR2 may be seated on the transfer 270. In this case, the cassette driving portion 283 may be disposed so that the second tray TR2 is spaced apart from an upper part of the transfer 270. When the transfer 270 is disposed at a lower part of the second tray TR2, the cassette driving portion 283 may descend the cassette 282 so that the second tray TR2 may be seated on the transfer 270.

When the belt 241 rotates again, the transfer 270 may be transported to the tray transporting portion 240 from the second chamber 281. The tray transporting portion 240 may transport the second tray TR2 seated on the transfer 270 to correspond to the transmission window 212.

When the first tray TR1 is transported or the second tray TR2 is transported as described above, the sensor portion 250 may apply a signal to an outer surface of the belt 241 to detect a reflected signal again. In an embodiment, for example, as described above, the sensor portion 250 may detect the mark 241a arranged on the outer surface of the belt 241 or may detect the outer surface of the belt 241 on which the mark 241a is arranged. In an alternative embodiment, when the belt 241 has a shape of a timing belt, the outer surface of the belt 241 may be bent. At this time, the time at which a signal generated in the sensor portion 250 collides with protruding or inserted portions of the belt 241 and is reflected and then returns to the sensor portion 250, may be different according to the shape of the outer surface of the belt 241. In an embodiment, the bending of the outer surface of the belt 241 may have constant patterns, and the protruding portions of the outer surface of the belt 241 may be disposed to be spaced apart from each other by a certain distance.

The controller 293 may calculate the position of one point of the belt 241 or a distance at which one point of the belt 241 moves, based on the detected result as described above. Herein, for convenience of description, embodiments where the controller 293 calculates the distance at which one point of the belt 241 moves, are described in detail.

In embodiments, as described above, the distance at which one point of the belt 241 calculated by the controller 293 may be an actual movement distance L1. In such an embodiment, a signal movement distance L2 at which one point of the belt 241 disposed to allow the first tray TR1 or the second tray TR2 to correspond to the transmission window 212 from one point, may be pre-set in the controller 293. In this case, the controller 293 may apply a signal to the driving portion 244 so that one point of the belt 241 moves by the signal movement distance L2. Based on the signal, the driving portion 244 may operate, and the rotation degree of the driving portion 244 may be detected by an encoder of the driving portion 244 and may be transmitted to the controller 293. The controller 293 may determine that one point of the belt 241 has moved from a certain position by the signal movement distance L2 based on the signal.

In a case where the second tray TR2 moves, the second tray TR2 may be disposed in a reference position PO when being moved to the transfer 270. In this case, the reference position PO may be a position in which one side surface of the second tray TR2 is disposed.

Subsequently, when the second tray TR2 is moved according to a signal as pre-set, the second tray TR2 may be desired to be arranged in a first position P01. However, when the belt 241 or the like is expanded or a tensile force applied to the belt 241 is reduced, a position where the second tray TR2 is actually moved according to the operation of the driving portion 244, may be a second position P02 different from the first position P01. In this case, the signal movement distance L2 may be a distance between the reference position PO and the first position P01, and the actual movement distance L1 may be a distance between the reference position PO and the second position P02.

In an embodiment, the controller 293 may calculate a distance difference ΔL between the actual movement distance L1 and the signal movement distance L2 as described above. In this case, the distance difference ΔL may mean a value obtained by subtracting the actual movement distance L1 from the signal movement distance L2. The controller 293 may adjust the position of the second pulley 243 based on the distance difference ΔL so that the distance difference ΔL between the actual movement distance L1 and the signal movement distance L2 may be 0. In this case, the relationship between distances at which the second pulley 243 is pre-set to be moved from an initial position of the second pulley 243 according to the distance difference ΔL, may be stored in the controller 293 in the form of numerical data. When the distance difference ΔL is calculated, the controller 293 may determine a distance at which the second pulley 243 is determined to be moved to correspond to the distance difference ΔL. In this case, a distance (or gap) between the first pulley 242 and the second pulley 243 may be increased or decreased from an initial distance therebetween. In an embodiment, for example, when the distance difference ΔL has a positive value, a distance between the first pulley 242 and the second pulley 243 may be greater than the initial distance.

The controller 293 may control the position adjusting portion 245 based on the above result to vary the position of the second pulley 243. In an alternative embodiment, where the position adjusting portion 245 is connected to the first pulley 242, the controller 293 may control the position adjusting portion 245 in a similar manner to those described above. The position adjusting portion 245 may adjust a distance between the first pulley 242 and the second pulley 243 based on a result of determining whether the belt 241 is abnormal.

After the above-described process is completed, the controller 293 may return the second tray TR2 to its initial position. In this case, whether the second tray TR2 returns to its initial position, may be checked by detecting the presence of the second tray TR2 through the sensor portion 250.

When it is determined through the above-described process that the tensile force of the belt 241 is the same as or similar to an initially-set tensile force, the controller 293 may control the apparatus 200 for manufacturing a display device to perform an operation on the display substrate 20 after arranging the second tray TR2 to correspond to the transmission window 212 again.

In an embodiment, when the actual movement distance L1 is greater than the signal movement distance L2, control in an opposite manner to those described above may be performed. That is, the position adjusting portion 245 may also be controlled so that the distance between the first pulley 242 and the second pulley 243 is reduced compared to the initial distance.

Thus, in embodiments of the apparatus 200 for manufacturing a display device and a method of manufacturing a display device, the tensile force of the belt 241 may be precisely adjusted so that a tray may be arranged in a working position. Also, in embodiments of the apparatus 200 for manufacturing a display device and a method of manufacturing a display device, the tray may be replaced with another one so that time for manufacturing may be reduced. In embodiments of the apparatus 200 for manufacturing a display device and a method of manufacturing a display device, a work using laser beams may be performed regardless of the size of the substrate of the display substrate 20.

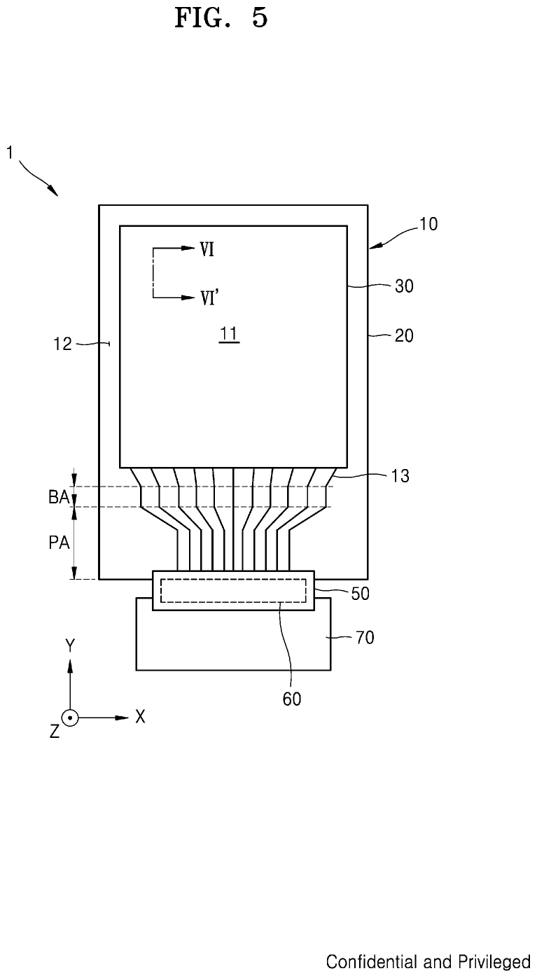

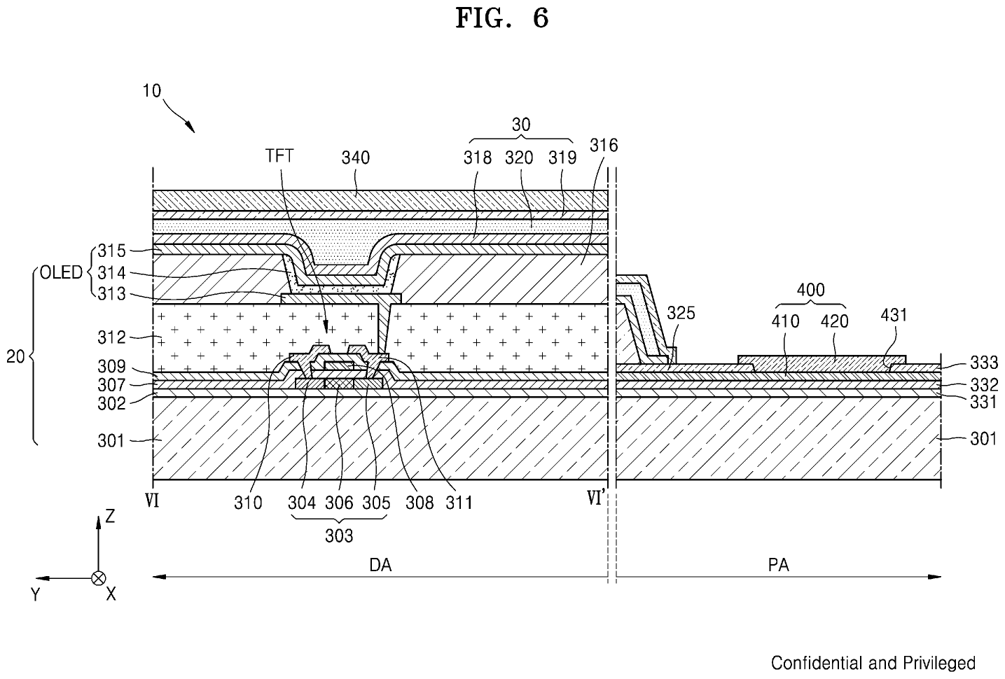

FIG. 5 is a plan view schematically illustrating a display device according to an embodiment. FIG. 6 is a cross-sectional view of the display device taken along line VI-VI′ of FIG. 5.

Referring to FIGS. 5 and 6, an embodiment of a display device 1 may include a display panel 10. In an embodiment, the display device 1 may be an organic light emitting display device OLED. However, the display device 1 is not limited thereto, and alternatively, the display device 1 may include one of an inorganic light emitting display apparatus, a quantum dot light emitting display apparatus, a field emission display apparatus, a surface-conduction electron-emitter display apparatus, and a plasma display apparatus.

The display panel 10 may include a display substrate 20 including a plurality of elements therein, and a thin film encapsulation layer 30 arranged on the display substrate 20. A plurality of thin film transistors TFTs and a plurality of light emitting elements connected to the plurality of thin film transistors TFTs may be arranged in the display substrate 20. A functional film such as a polarizing plate, a touch screen 340, and a cover window may be arranged on the thin film encapsulation layer 30.

A display area 11 in which an image is displayed, and a peripheral area 12 extending to the outside of the display area 11 may be arranged on the display panel 10. In this case, an image may not be displayed in the peripheral area 12.

The thin film encapsulation layer 30 may cover the display area 11.

The peripheral area 12 may surround the display area 11. In an embodiment, a bending area BA in which the display panel 10 may be folded in one direction, and a pad area PA extending to the outside of the bending area BA may be arranged in the peripheral area 12. However, embodiments of the disclosure are not limited thereto, and the bending area BA may also be formed in the display area 11. In an alternative embodiment, the bending area BA may not be present in the peripheral area 12, and the peripheral area 12 may also extend to the pad area PA. However, herein, for convenience of description, embodiments where the peripheral area 12 includes the bending area BA and the pad area PA and the bending area BA is formed in the peripheral area 12, will be described.

The bending area BA described above may have various shapes. In an embodiment, the bending area BA may have a same width (e.g., measured in an X-axis direction of FIG. 5) as the display area 11 and the peripheral area 12, as shown in FIG. 5. In an alternative embodiment, although not shown in FIG. 5, the width of the bending area BA may be reduced as being away from the display area 11. Also, the width of the bending area BA may be constant at a certain distance in a portion of the bending area BA connected to the display area 11. In this case, the side edge of the bending area BA may be a rounded shape.

The display panel 10 may be folded in one direction based on a bending line that is a reference line arranged in the bending area BA. In this case, the bending line may be arranged in the bending area BA based on FIG. 5 and may be arranged in the X-axis direction of FIG. 5. However, embodiments of the disclosure are not limited thereto, and the display area 11 and the pad area PA may be connected to each other without the bending area BA. That is, the display panel 10 may also be configured to be rigid without a bending line. However, herein, for convenience of description, the display panel 10 having a configuration that may be folded in one direction based on the bending line will be described.

The pad area PA may be at one edge of the display substrate 20. A plurality of pad terminals 400 may be arranged in the pad area PA. The plurality of pad terminals 400 may be disposed to be spaced apart from each other in X-axis and Y-axis directions of the display substrate 20. The pad terminals 400 may be connected to a wiring 13 extending from the display area 11.

The plurality of pad terminals 400 may be electrically connected to a display device driving portion (not shown) through a film member 50.

The display device driving portion may include a driving circuit and may be a chip on film (COF). However, the display device driving portion is not limited thereto, and alternatively, for example, the display device driving portion may be a chip on plastic (COP) or a chip on glass (COG).

The display device driving portion may include a film member 50 in which a circuit wiring is patterned, a driving chip 60 arranged on the film member 50, and a plurality of driving terminals (not shown) arranged on a lower part of the driving chip 60. The film member 50 and the driving chip 60 may be electrically connected to each other.

The film member 50 may be electrically connected to the circuit board 70. The circuit board 70 may be a flexible printed circuit board (FPCB).

The plurality of pad terminals 400 and the terminals of the film member 50 may be electrically connected to each other, and the film member 50 and the plurality of driving terminals may be electrically connected to each other. In an embodiment, each pad terminal 400 and each terminal of the film member 50 arranged to correspond to each other may be directly or indirectly electrically connected to each other. In an embodiment where each pad terminal 400 and each terminal of the film member 50 are indirectly connected to each other, as described above, each pad terminal 400 and each terminal of the film member 50 may be electrically connected to each other via an anisotropic conductive film or the like.

The display area DA (ex, a portion of the display area 11 or sub-pixel area) provided in the display area 11 and the pad area PA provided in the peripheral area 12 may be arranged or defined on a substrate 301.

The substrate 301 may be a flexible glass substrate, a flexible polymer substrate, a rigid glass substrate, or a rigid polymer substrate. The substrate 301 may be transparent, semi-transparent, or opaque. However, herein, for convenience of description, embodiments where the substrate 301 is a flexible polymer substrate, are described in detail.

A barrier layer 302 may be arranged on the substrate 301. The barrier layer 302 may be configured to cover an upper surface of the substrate 301. The barrier layer 302 may be an organic layer or an inorganic layer. The barrier layer 302 may be a single layer or a multi-layered layer.

At least one thin film transistor TFT may be arranged in the display area DA. In an embodiment, the number of thin film transistors TFTs is not limited to one, that is, more than one thin film transistor TFT may be arranged in the display area DA.

A semiconductor active layer 303 may be arranged on the barrier layer 302. The semiconductor active layer 303 may include a source region 304 and a drain region 305, which are arranged by doping N-type impurity ions or P-type impurity ions. A channel region 306 in which no impurity is doped, may be between the source region 304 and the drain region 305. The semiconductor active layer 303 may be an organic semiconductor, an inorganic semiconductor, or amorphous silicon. In an embodiment, the semiconductor active layer 303 may be an oxide semiconductor.

A gate insulating layer 307 may be deposited on the semiconductor active layer 303. The gate insulating layer 307 may be an organic layer and/or an inorganic layer. Also, the gate insulating layer 307 may have a single layer structure or multi-layered structure including at least one of the organic layer and the inorganic layer. In this case, the gate insulating layer 307 is not limited to those described above and may be modified in various forms.

A gate electrode 308 may be arranged on the gate insulating layer 307. The gate electrode 308 may include or be formed of a metal material having conductivity. In an embodiment, for example, the gate electrode 308 may include at least one selected from molybdenum (Mo), aluminum (Al), copper (Cu), and titanium (Ti). The gate electrode 308 may have a single layer structure and/or multi-layered structure including at least one selected from Mo, Al, Cu, and Ti. In this case, the gate electrode 308 is not limited to those described above and may be modified in various forms.

An interlayer insulating layer 309 may be arranged on the gate electrode 308. The interlayer insulating layer 309 may be an organic layer and/or an inorganic layer.

A source electrode 310 and a drain electrode 311 may be arranged on the interlayer insulating layer 309. A contact hole may be defined in, or formed by removing a portion of, the gate insulating layer 307 and a portion of the interlayer insulating layer 309, and the source electrode 310 is electrically connected to the source region 304 through the contact hole, and the drain electrode 311 may be electrically connected to the drain region 305 through the contact hole.

The source electrode 310 and the drain electrode 311 may include or be formed of a metal material having high conductivity. In an embodiment, for example, the source electrode 310 and the drain electrode 311 may include at least one selected from Mo, Al, Cu, and Ti. The source electrode 310 and the drain electrode 311 may have a single layer structure and/or multi-layered structure including at least one of Mo, Al, Cu, and Ti. In an embodiment, for example, the source electrode 310 and the drain electrode 311 may have a structure in which Ti/Al/Ti are stacked. In this case, the source electrode 310 and the drain electrode 311 is not limited to those described above, may include various materials and may be formed to have various structures.

A protective layer 312 may be arranged on the source electrode 310 and the drain electrode 311. The protective layer 312 may be an organic layer or an inorganic layer. The protective layer 312 may be a passivation layer or a planarization layer. One of the passivation layer and the planarization layer may be omitted.

The thin film transistor TFT may be electrically connected to an organic light emitting display device OLED.

The organic light emitting display device OLED may be arranged on the protective layer 312. The organic light emitting display device OLED may include a first electrode 313, an intermediate layer 314, and a second electrode 315.

The first electrode 313 may function as an anode and may include or be formed of at least one selected from various conductive materials. The first electrode 313 may include a transparent electrode or a reflective electrode. In an embodiment, for example, where the first electrode 313 is the transparent electrode, the first electrode 313 includes a transparent conductive layer. In an embodiment, for example, where the first electrode 313 is the reflective electrode, the first electrode 313 may include a reflective layer and a transparent conductive layer arranged on the reflective layer. In an embodiment, the first electrode 313 may have a structure in which indium tin oxide (ITO)/Ag/ITO are stacked.

The first electrode 313 described above may be connected to the drain electrode 311 or the source electrode 310. Herein, for convenience of description, embodiments where the first electrode 313 is connected to the drain electrode 311, are described in detail.

A pixel defining layer 316 may be arranged on the protective layer 312. The pixel defining layer 316 may be configured to cover a portion of the first electrode 313. The pixel defining layer 316 may define an emissive region of each sub-pixel by surrounding the edge of the first electrode 313. The first electrode 313 may be patterned in each sub-pixel. The pixel defining layer 316 may be an organic layer and/or an inorganic layer. The pixel defining layer 316 may have a single layer structure or multi-layered structure including at least one of the organic layer and the inorganic layer. In this case, the pixel defining layer 316 is not limited to those described above and may be modified in various forms.

The intermediate layer 314 may be arranged in a region of the first electrode 313 exposed by etching a portion of the pixel defining layer 316. The intermediate layer 314 may be formed by a deposition process.

The intermediate layer 314 may include an organic emissive layer.

In another alternative, example, the intermediate layer 314 may include an organic emissive layer, and may further include at least one of a hole injection layer (HIL), a hole transport layer (HTL), an electron transport layer (ETL), and an electron injection layer (EIL) in addition to the organic emissive layer.

In an embodiment, the intermediate layer 314 may include an organic emissive layer, and may further include other various functional layers.

The second electrode 315 may be arranged on the intermediate layer 314.

The second electrode 315 may function as a cathode electrode. The second electrode 315 may include a transparent electrode or a reflective electrode. In an embodiment, for example, where the second electrode 315 is used as a transparent electrode, the second electrode 315 may include a metal layer, and a transparent conductive layer arranged on the metal layer. In an embodiment, for example, where the second electrode 315 is used as the reflective electrode, the second electrode 315 may include the metal layer.

In an embodiment, a plurality of sub-pixels may be formed on the substrate 301. In an embodiment, for example, red, green, blue or white colors may be implemented in each sub-pixel. However, embodiments of the disclosure are not limited thereto.

The thin film encapsulation layer 30 may cover the organic light emitting display device OLED.

The thin film encapsulation layer 30 may be formed when inorganic layers 318 and 319 and an organic layer 320 are alternately stacked to each other. in an embodiment, for example, a first inorganic layer 318, an organic layer 320, and a second inorganic layer 319 may be sequentially stacked on the organic light emitting display device OLED. In an embodiment, the stack structure of the inorganic layer and the organic layer provided in the thin film encapsulation layer 30 may be variously modified.

A touch screen 340 may be installed on the thin film encapsulation layer 30. In an embodiment, the touch screen 340 may be a touch screen of an electrostatic capacitive type. In such an embodiment, a base layer (not shown) may be arranged on the thin film encapsulation layer 30. A plurality of touch electrode wirings (not shown) may be arranged on the base layer. In an embodiment, the plurality of touch electrode wirings may have a structure in which Ti/Al/Ti are stacked. In an alternative embodiment, a base layer in the touch screen 340 may be omitted. The touch electrode wirings may be covered by a touch electrode insulating layer (not shown). The touch electrode insulating layer may be an organic layer or an inorganic layer.

A first insulating layer 331 may be arranged in the pad area PA of the substrate 301. The first insulating layer 331 may be arranged in a same layer as the barrier layer 302. That is, the first insulating layer 331 may include or be formed of a same material in the same process as the barrier layer 302.

A second insulating layer 332 may be arranged on the first insulating layer 331. The second insulating layer 332 may be arranged on the same layer as the gate insulating layer 307. That is, the second insulating layer 332 may be formed of the same material in a same process as the gate insulating layer 307.

A first conductive layer 410 provided on each pad terminal 400 may be arranged on the second insulating layer 332. The first conductive layer 410 may be electrically connected to a wiring 325 extending from the display area DA. The first conductive layer 410 may be arranged in a same layer as the gate electrode 308. That is, the first conductive layer 410 may include or be formed of a same material in a same process as the gate electrode 308. Each first conductive layer 410 may be disposed to be spaced apart from each other in one direction of the substrate 301.

A third insulating layer 333 may be arranged on the first conductive layer 410. The third insulating layer 333 may be arranged in a same layer as the interlayer insulating layer 309. The third insulating layer 333 may include or be formed of a same material in a same process as the interlayer insulating layer 309. In an embodiment, the third insulating layer 333 may be an organic layer or an inorganic layer.

The third insulating layer 333 may cover at least a portion of the first conductive layer 410. A contact hole 431 may be defined or formed in the third insulating layer 333 to expose a portion of the first conductive layer 410 by removing a portion of the third insulating layer 333. An upper surface of the first conductive layer 410 may be exposed to the outside in a region in which the contact hole 431 is formed.

A second conductive layer 420 may be arranged on the first conductive layer 410. The second conductive layer 420 having an island shape may be arranged on the first conductive layer 410. In an alternative embodiment, the second conductive layer 420 may be electrically connected to the wiring 325 extending from the display area DA.

The second conductive layer 420 may be arranged in a same layer as the source electrode 310 and the drain electrode 311. That is, the second conductive layer 420 may include or be formed of a same material in a same process as the source electrode 310 and the drain electrode 311. In an embodiment, the second conductive layer 420 may include a plurality of layers and may have a structure in which layers including at least one of Al and Ti are stacked on each other. In embodiments, the stack structure of the second conductive layer 420 may be Al/Ti/Al/Al or Ti/Al/Ti, for example. In this case, the second conductive layer 420 is not limited to those described above and may include various materials or various structures.

Referring to FIG. 6, the second conductive layer 420 may be electrically connected to the first conductive layer 410 through the contact hole 431. That is, the second conductive layer 420 may be electrically connected to the first conductive layer 410 in a region in which the third insulating layer 333 is not present. The first conductive layer 410 and the second conductive layer 420 may form a contact portion in a region in which the contact hole 431 is formed.

The second conductive layer 420 may extend to a partial region of the first conductive layer 410 exposed through the contact hole 431 and a region in which the third insulating layer 333 for covering the first conductive layer 410 is arranged.

The first conductive layer 410 and the second conductive layer 420 may not be electrically connected to each other in all regions, and may be connected to each other via the contact hole 431 in which a part of the third insulating layer 333 is removed. A portion of the second conductive layer 420 may be arranged in the exposed region of the first conductive layer 410 through the contact hole 431, and another portion of the second conductive layer 420 may be arranged on the third insulating layer 333.

Terminals of the film member 50 may be electrically connected to each other on the pad terminal 400. Also, the film member 50 may be electrically connected to the driving terminal. Circuit patterns may be arranged on a lower part of the driving chip 60. The driving terminals may include at least one selected from gold (Au), nickel (Ni), and tin (Sn). In this case, the driving terminals are not limited to those described above and may include various materials.

In embodiments, the first conductive layer 410 and the second conductive layer 420 may be arranged in a same layer as other metal layers arranged on the substrate 301 of FIG. 6, for example, metal layers selected from the first electrode 313, the second electrode 315, and the touch electrode in addition to the gate electrode 308, the source electrode 310, and the drain electrode 311.

In an embodiment, the third insulating layer 333 may be arranged in a same layer as an insulating layer selected from the gate insulating layer 307, the protective layer 312, the pixel defining layer 316, the thin film encapsulation layer 30, and the touch electrode insulating layer, which are patterned on the substrate 301 of FIG. 6, in addition to the interlayer insulating layer 309.

A plurality of pad terminals 400 electrically connected to the terminal of the film member 50 may be arranged in the pad area PA. Each pad terminal 400 of the plurality of pad terminals 400 may be disposed to be spaced apart from each other in one direction of the substrate 301.

The film member 50 and the display panel 10 described above may be bonded to each other.

An apparatus for manufacturing a display device and a method of manufacturing a display device according to one or more embodiments of the disclosure may be effectively operable on a large substrate.

In an apparatus for manufacturing a display device and a method of manufacturing a display device according to one or more embodiments, the tensile force of a belt may be precisely adjusted so that a process may be effectively performed.

In an apparatus for manufacturing a display device and a method of manufacturing a display device according to one or more embodiments, a display device having a uniform quality may be manufactured.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. An apparatus for manufacturing a display device, the apparatus comprising:
a tray on which a window is seated;
a belt on which the tray is seated and is moved;
a first pulley which rotatably supports the belt;
a second pulley disposed to be spaced apart from the first pulley, wherein the second pulley rotatably supports the belt; and
a driving portion connected to the second pulley, wherein the driving portion rotates the second pulley.

2. The apparatus of claim 1, further comprising:
a sensor portion which detects a position of one point of the belt.

3. The apparatus of claim 2, further comprising:
a controller which determines whether the belt is abnormal based on the position of the one point detected by the sensor portion.

4. The apparatus of claim 3, further comprising:
a position adjusting portion which adjusts a distance between the first pulley and the second pulley based on a result of determining whether the belt is abnormal.

5. The apparatus of claim 1, further comprising:
a chamber in which the belt, the first pulley and the second pulley are disposed.

6. The apparatus of claim 5, further comprising:
a tray providing portion connected to the chamber, wherein the tray providing portion provides a new tray, in which a new window is disposed, to the belt.

7. The apparatus of claim 5, further comprising:
a laser irradiating portion disposed outside the chamber, wherein the laser irradiating portion radiates a laser into the chamber.

8. The apparatus of claim 7, further comprising:
a transmission window, which is disposed in the chamber and through which the laser transmits.

9. The apparatus of claim 1, further comprising:
a substrate fixing portion disposed on the tray, wherein the substrate fixing portion fixes a substrate thereto.

10. A method of manufacturing a display device, the method comprising:
arranging a substrate in a chamber;
moving a first tray, in which a first window is disposed, to a position in the chamber corresponding to the substrate;
detecting a position of one point of a belt when the first tray is moved; and
determining whether the belt is abnormal based on the position of the one point of the belt.

11. The method of claim 10, further comprising:
maintaining a pressure inside the chamber to be lower than an atmospheric pressure.

12. The method of claim 10, further comprising:
replacing the first tray with a second tray, in which a second window is disposed, by using a tray providing portion connected to the chamber.

13. The method of claim 10, further comprising:
radiating a laser onto the substrate by passing through the first window.

14. The method of claim 10, further comprising:
comparing an actual movement distance of the first tray, at which the first tray is actually moved, with a signal movement distance at which the first tray is pre-set to be moved in response to an external signal.

15. The method of claim 14, further comprising:
comparing the actual movement distance with the signal movement distance to adjust a tensile force of the belt.
